(19) United States
(12) Patent Application Publication
(10) Pub. No.: US 2026/0046174 A1
(43) Pub. Date: Feb. 12, 2026

(54) FULL DUPLEX DIGITAL ISOLATOR

(71) Applicant: Navitas Semiconductor Limited, Dublin (IE)

(72) Inventors: Vincent DESSARD, Moint-Saint-Guibert (BE); Aimad SAIB, Gembloux (BE); Stéphane ADRIAENSEN, Limelette (BE); Xavier BAIE, Gembloux (IE); Daniel M. KINZER, El Segundo, CA (US); Marco GIANDALIA, Marina Del Rey, CA (US)

(73) Assignee: Navitas Semiconductor Limited, Dublin (IE)

(21) Appl. No.: 19/294,057

(22) Filed: Aug. 7, 2025

Related U.S. Application Data
(60) Provisional application No. 63/681,463, filed on Aug. 9, 2024.

(51) Int. Cl. H04L 25/02; H03K 19/0175

(52) U.S. Cl. CPC H04L 25/0266; H03K 19/017509; H04L 25/026; H04L 25/0272

(57) ABSTRACT

A circuit. The circuit includes a first transmitter circuit having a first input terminal arranged to receive a first input data and a first node arranged to transmit a first intermediate data corresponding to the first input data, a first receiver circuit including a second node arranged to receive the first intermediate data and a first output terminal arranged to produce a first output data corresponding to the first input data, a second transmitter circuit including a second input terminal arranged to receive a second input data and the second node that is further arranged to transmit a second intermediate data corresponding to the second input data; and a second receiver circuit including the first node and a second output terminal, the first node further arranged to receive the second intermediate data, and the second output terminal arranged to produce a second output data corresponding to the second input data.

### CROSS REFERENCE TO RELATED APPLICATIONS

This application claims priority to US provisional Ser. No. 63/681,463, for “FULL DUPLEX DIGITAL ISOLATOR” filed on Aug. 9, 2024, which is hereby incorporated by reference in entirety for all purposes.

### FIELD

The described embodiments relate generally to galvanic isolation in power converters, and more particularly, the present embodiments relate to full duplex digital isolators for signal isolation in power converters.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices. Power converters may utilize isolators. Isolators can be implemented to separate circuits or circuit sections of the electrical circuit to one another from undesired influence of, for example but not limited to, other circuits or circuit sections, to minimize the influence of common mode transients (CMT), influence of radiation or electromagnetic interferences, cross talk, between circuits or circuit sections. Capacitive isolation can be used in galvanic isolation, to isolate high voltages from one another or to isolate low voltage command circuits to high voltage power circuits.

### SUMMARY

In some embodiments, a circuit is disclosed. The circuit includes a first transmitter circuit including a first input terminal arranged to receive a first input data and a first node arranged to transmit a first intermediate data corresponding to the first input data; a first receiver circuit including a second node arranged to receive the first intermediate data and a first output terminal arranged to produce a first output data corresponding to the first input data; a second transmitter circuit including a second input terminal arranged to receive a second input data and the second node, the second node further arranged to transmit a second intermediate data corresponding to the second input data; and a second receiver circuit including the first node and a second output terminal, the first node further arranged to receive the second intermediate data, and the second output terminal arranged to produce a second output data corresponding to the second input data.

In some embodiments, the first node includes a first pair of differential isolation capacitors.

In some embodiments, the second node includes a second pair of differential isolation capacitors.

In some embodiments, each of the first pair of differential isolation capacitors includes a first top plate and a first bottom plate, each of the first top plates coupled to the second node and each of the first bottom plates coupled to the first transmitter circuit.

In some embodiments, each of the first pair of differential isolation capacitors further includes a second top plate attached to the first top plate and a second bottom plate separate from the first bottom plate.

In some embodiments, each of the second top plates is coupled to the second node and each of the second bottom plates is coupled to the second receiver circuit.

In some embodiments, each of the second pair of differential isolation capacitors includes a third top plate and a third bottom plate, each of the third top plates coupled to a corresponding first top plate.

In some embodiments, each of the third bottom plates is coupled to the first receiver circuit.

In some embodiments, each of the second pair of differential isolation capacitors further includes a fourth top plate attached to the third top plate and a fourth bottom plate separate from the third bottom plate.

In some embodiments, each of the fourth bottom plates is coupled to the second transmitter circuit.

In some embodiments, the first transmitter circuit and the second receiver circuit are arranged to operate with respect to a first ground, and the first receiver circuit and the second transmitter circuit are arranged to operate with respect to a second ground.

In some embodiments, the second input data include fault data from a high-side of a half-bridge circuit.

In some embodiments, the second input data include over-temperature or over-current condition data from a high-side of a half-bridge circuit.

In some embodiments, a method of operating a circuit is disclosed. The method includes providing a first transmitter circuit including a first input terminal and a first node; providing a first receiver circuit including a second node and a first output terminal; providing a second transmitter circuit including a second input terminal and the second node; providing a second receiver circuit including the first node and a second output terminal; receiving a first input data, by the first transmitter circuit; transmitting a first intermediate data, by the first transmitter circuit, corresponding to the first input data; receiving the first intermediate data, by the second receiver circuit; and producing a first output data, by the first receiver circuit, corresponding to the first input data.

In some embodiments, the method further includes receiving a second input data, by the second transmitter circuit; transmitting a second intermediate data, by the second transmitter circuit, corresponding to the second input data; receiving the second intermediate data, by the second receiver circuit; and producing a second output data, by the second receiver circuit, corresponding to the second input data.

In some embodiments, a circuit is disclosed. The circuit includes a first transmitter circuit having a first input terminal arranged to receive first input data and a first node arranged to transmit a first intermediate data corresponding to the first input data; a first receiver circuit having a second node arranged to receive the first intermediate data and a first output terminal arranged to produce a first output data corresponding to the first input data; and a second transmitter circuit having a second input terminal arranged to receive a second input data and the second node, the second node further arranged to transmit a second intermediate data corresponding to the second input data.

### BRIEF DESCRIPTION OF THE DRAWINGS

FIG. 1 illustrates a full duplex digital isolator, according to some embodiments;

FIGS. 2A and 2B illustrate a data modulation scheme for forward channel of the full duplex digital isolator of FIG. 1, according to some embodiments; and

FIGS. 3A and 3B illustrate a full duplex communication scheme with multiplexed return channel, according to some embodiments.

### DETAILED DESCRIPTION

Circuits, devices, and related techniques disclosed herein relate generally to galvanic isolation in power converters. More specifically, circuits, devices and related techniques disclosed herein relate to full duplex digital isolators in power converters and traction inverters. In some embodiments, the full duplex digital isolator can include bidirectional data transmission. In various embodiments, the full duplex digital isolator can have a feedback channel in addition to the forward channel. The feedback channel can be arranged to transmit back status information and/or transmit low bitstream data such as, but not limited to, operating temperature of a power converter and/or fault condition signals. Circuits and techniques disclosed herein enable the use of relatively low speed in the feedback channel.

Further, techniques disclosed herein can generate transmission-back data that may have relatively relaxed distortion constraints. In current approaches, a specific reverse channel may be used for transmission back. This can have relatively high costs due to the use of additional high voltage capacitors and/or transformers. It can also have relatively high current consumption. Moreover, use of a specific reverse channel can increase the die size and limit the packaging choices. Embodiments of the disclosure enable transmission back of data through the same isolator channel without use of an extra differential capacitively isolated channel.

In some embodiments, the full duplex digital isolator may include a forward isolation channel using differential capacitors and a feedback channel that can use the same differential capacitors. The forward channel can include a transmitter, an isolator and a receiver. The transmitter may include a first modulator and a first driver and be arranged to receive input data and generate output data that is transmitted through differential capacitors to the receiver. The receiver may include a first receiver and a first demodulator, and can be arranged to receive signals from the differential capacitors. The transmitter may operate referenced to a first ground (low ground) and the receiver may operate referenced to a second ground (high ground).

The feedback channel may have a feedback channel transmitter that includes a second modulator and a second driver, and can be arranged to transmit feedback data through the same differential capacitors. The feedback channel can further include a feedback receiver that can include a second receiver and a second demodulator. The isolation capacitors can use the same top plates used for transmitting forward data, but additional can include differential bottom plates. In some embodiments, the capacitive isolation channel may include a common top plate and split bottom plates. In this way, the number of high voltage bonding wires between the low voltage ground die and the high voltage ground die can stay the same, thereby saving costs and package space.

In various embodiments, the forward channel can include a transmitter circuit with an input terminal arranged to receive input data and a transmission node arranged to transmit intermediate data corresponding to the input data. The forward channel can also include a receiver circuit having a receive node arranged to receive the intermediate data and an output terminal arranged to produce output data corresponding to the input data. The forward channel can further include a dV/dt detector circuit that controls production of the output data based at least in part on a rate of change of a sensed voltage.

In some embodiments, a power converter may use gallium nitride (GaN)-based swicthes or silicon carbide (SiC)-based switches. These switches can operate at relatively high frequencies and can switch relatively fast compared to silicon-based switches, thus relatively fast dV/dt events may occur in these power converters causing substantial ringing and EMI.

Embodiments of the disclosure can handle relatively fast dV/dt events, thereby assuring integrity of data transfer, reducing ringing and reducing EMI. Further, embodiments of the disclosure can reduce parasitic elements in the data transmitting channel, further reducing ringing and EMI. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

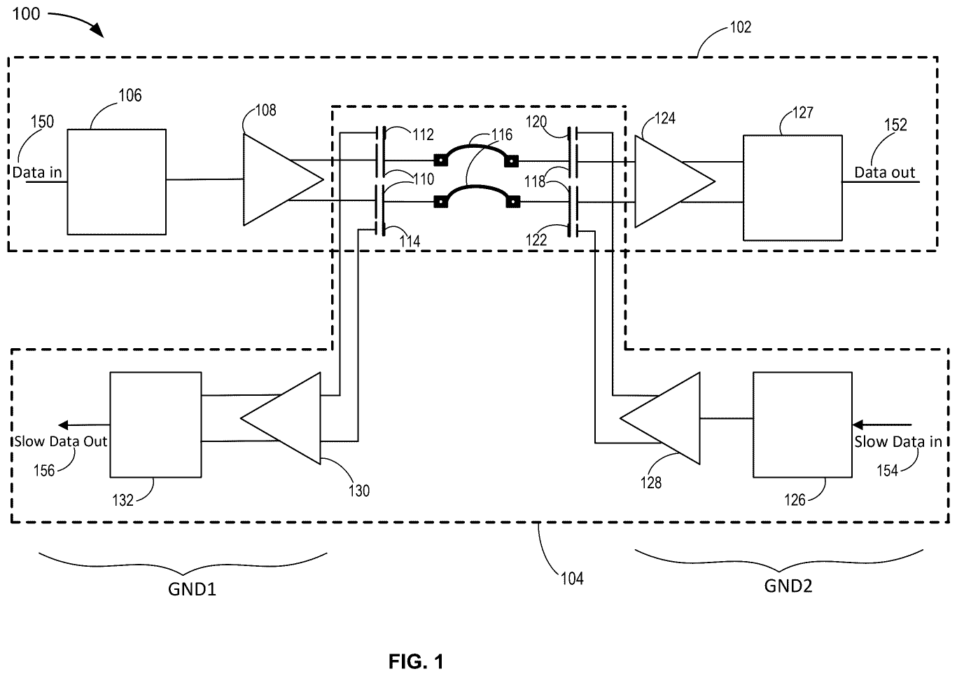

FIG. 1 illustrates a full duplex digital isolator, according to some embodiments. A full duplex digital isolator 100 can include a forward channel 102 and a feedback channel 104. The forward channel 102 may include a modulator 106 and a driver 108. The modulator 106 and the driver 108 can form a transmitter section of the forward channel 102. The driver 108 may be differentially coupled to a differential capacitor 110. The differential capacitor 110 can be coupled to a differential capacitor 118 by wirebonds 116. The differential capacitor 118 can be coupled to a receiver 124. The receiver 124 can be coupled to a demodulator 127. The receiver 124 and the demodulator 127 can form a receiver section of the forward channel 102.

The feedback channel 104 may include a modulator 126 that is coupled to a driver 128. The modulator 126 and the driver 128 can form the transmitter section of the feedback channel 104. The driver 128 can be coupled to the differential capacitor 118. The differential capacitor 118 can be coupled to a differential capacitor 110 by wirebonds 116. The differential capacitor 110 can be coupled to a receiver 130. Receiver 130 can be coupled to a demodulator 132. The receiver 130 and the demodulator 132 can form a receiver section of the feedback channel 104. The forward channel 102 can be arranged to receive input data 150 and generate output data 152. The feedback channel 104 can be arranged to receive input data 154 and generate output data 156.

In order to enable the feedback channel to use the same isolation capacitors, each of the top plates of the differential capacitors 110 may be increased by a relatively small area as shown by 112 and 114. A relatively small bottom plate corresponding to 112 and 114 may also be added to each of the differential capacitors 110. Further, each of the top plates of the differential capacitor 118 may have a relatively small increase in size as shown by 120 and 122. A relatively small bottom plate corresponding to 120 and 122 may also be added to the differential capacitor 118. In this way, the feedback channel 104 can use the same isolation capacitors as the forward channel 102. The left side of the full duplex digital isolator 100 may operate referenced to GND1 while the right side of the full duplex digital isolator 100 may operate referenced to GND2. In some embodiments, GND1 may be a low voltage ground and GND2 may be a high voltage ground.

In some embodiments, receiver 124 may operate with a level of common-mode current that is used for relatively high levels of dV/dt events. This can reduce the sensitivity of the receiver 124 since the receiver 124 may use a relatively low value for the common-mode input impedance. Circuit and techniques disclosed herein enable use of the receiver 130 that can operate with reduced dV/dt robustness because the feedback channel 104 may transmit at relatively low data rates in absence of dV/dt events. In this way, the sensitivity of receiver 130 can be increased, thereby enabling relatively small input differential signal. Thus, the added capacitor plate sections 112, 114, 120 and 122 can have a relatively small size. In some embodiments, the size increase of the differential capacitors 110 and 118 can be, for example, 10% to 20% of the original size.

In order to prevent a fault status signal transmitted by the feedback channel 104 from blocking transmission of data in the forward channel 102, the transmitter section of the feedback channel 104 can listen for transmission in the forward channel 102 before attempting to transmit data through the feedback channel. In this way, when a fault is detected on the high voltage section of the circuit, operating with reference to GND2, the low volage section, operating with reference to GND1, can prevent the transmitter section of the forward channel 102 from transmitting data during a fault condition, thus protecting the system. When the feedback channel 104 is transmitting a fault status signal, an output of forward channel 102 can determine whether there is a fault. When this condition occurs, the receiver 124 may ignore its input signal because its input signal may be corrupted by driver 128. The modulator 106 may not yet be aware that the secondary side is trying to send a fault status signal. The driver 108 can continue to transmit data between transitions, however driver 128 can transmit a relatively rapid fault signal that can be detected by receiver 130. In this way, driver 108 may continue to transmit data.

In some embodiments, the high voltage section of the circuit can self-protect by setting its output to zero. In various embodiments, this may be performed optionally with a soft turn-off and high voltage section of the circuit may stop listening to the low voltage section. In some embodiments, the high voltage section can attempt to send feedback through the feedback channel 104 to the low voltage section. In various embodiments, the transmitter section of the forward channel 102 may not continuously transmit transients at relatively high frequency, for example, in power electronics applications, where the bitstream may be relatively low, such as, below 1 Mb/s. In various embodiments, such as in pulse modulation, the transmitter on the forward channel 102 may be inactive during some time periods, for example, for several hundreds of nano seconds.

In such embodiments, the feedback channel 104 can transmit a modulated pattern that may be a HF carrier, for example, at several tens of MHz when a fault condition is to be reported. When the feedback channel 104 sends such pattern for several micro-seconds, there may be time periods that the forward channel's transmitter may be inactive such that the receiver 130 can be enabled to receive the feedback signal sent by the feedback channel 104. When the forward channel's transmitter is transmitting data, the receiver 130 can receive the same signal, where the received signal can be filtered and/or blanked. Under conditions of relatively high value dV/dt events, the input of the receiver 130 may go in its ESD rails, thus blanking any received signal. In such cases, receiver 130 can be self-blanking. When the dV/dt event is relatively small, the receiver 130 may be able to receive a feedback signal from the feedback channel's transmitter in case a fault is detected.

Referring to FIG. 1, when the low voltage section, operating referenced to GND1, determines that a fault condition is to be cleared, the fault feedback duration can be kept limited. In this embodiment, the full duplex digital isolator 100 can modulate the fault data on the feedback channel 104 for, for example, few micro-seconds, when the input data rate is below, for example, 1 Mb/sec. In some embodiments, the time period may be increased when a relatively high dv/dt is detected. In this way, the low voltage section may detect the fault within, for example, few micro-seconds. Once detected, the micro-controller on the low voltage section can disable the low voltage section for a desired time period. When the disable condition is removed, the high voltage side can be activated gain. The full duplex digital isolator 100 can repeat this sequence as long as a fault condition exist.

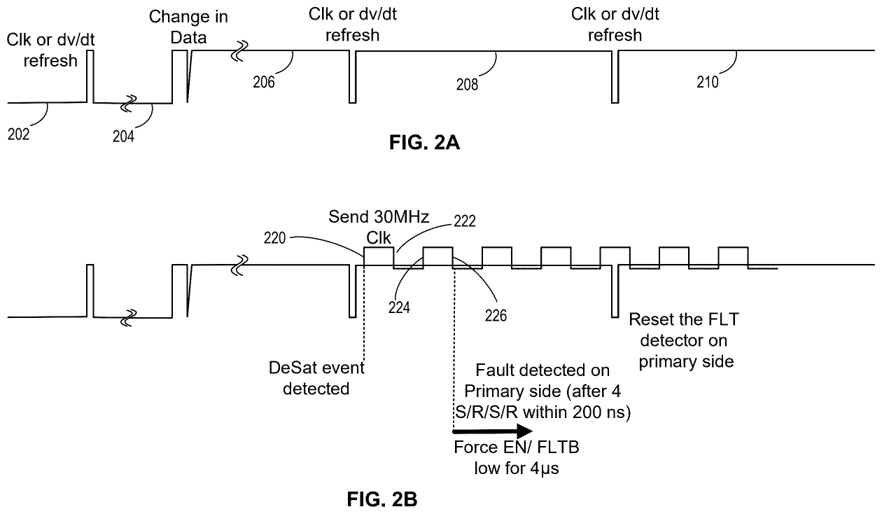

FIGS. 2A and 2B illustrate a data modulation scheme for forward channel 102, according to some embodiments. In some embodiments, the illustrated modulation scheme may be used for low power and/or low activity modulation. Sections 202, 204, 206, 208 and 210 are noted to be quiet periods. The forward channel transmitter may not be transmitting in the illustrated embodiment. For example, when CK=3 MHz, and data IN<1 MHz, each of sections 202, 204, 206, 208 and 210 are approximately 300 ns. In the illustrated example, when the feedback channel transmitter transmits back a 30 MHz carrier in case of fault during 4 μs, the forward channel transmitter can detect 4 consecutive edges [S (220)/R(222)/S(224)/R(226)], within 200 ns time period, thereby triggering a fault status (FLT) on the forward channel transmitter side. Any activity on the forward channel transmitter can either reset the fault detector receiver or may use digital filtering. The fault status may be detected within, for example, 1 μs.

Referring to FIG. 1, a full duplex communication scheme is described, according to some embodiments. The forward channel 102 can use a particular modulation where the information is transmitted on the edges. Each edge may be precisely detected, rising edge (Set) or falling edge (Reset). In this scheme, extra hgh-pass filtering may not be used as it may add tails after each edge. Due to various circuit mismatches, a minimum signal threshold may be used for detecting safely a Set or a Reset. The feedback channel 104 may use a scheme that is based on a relatively fast periodic signal, that may have a self-contained redundancy. In this way, a corresponding detector may not use a minimum detection threshold. In this modulation scheme, variations are to be detected. Thus, embodiments of the disclosure enable use of a receiver that may have more sensitivity to small signals. Extra filtering of the common mode current can be used since tails are not an issue in this scheme. In the disclosed full duplex communication scheme (fast forward, slow reverse), high frequency carrier used by the driver 128 may be relatively small so as not trig the receiver 124, but large enough to trigger the receiver 130. Embodiments of the disclosure enable use of the driver 108 in such a way as not to corrupt the data used by the receiver 130. Few edges may be used in the illustrated modulation scheme because of the relatively low frequency modulation of the forward channel 102. Digital filtering at demodulator 132 can remove such crosstalk pulses.

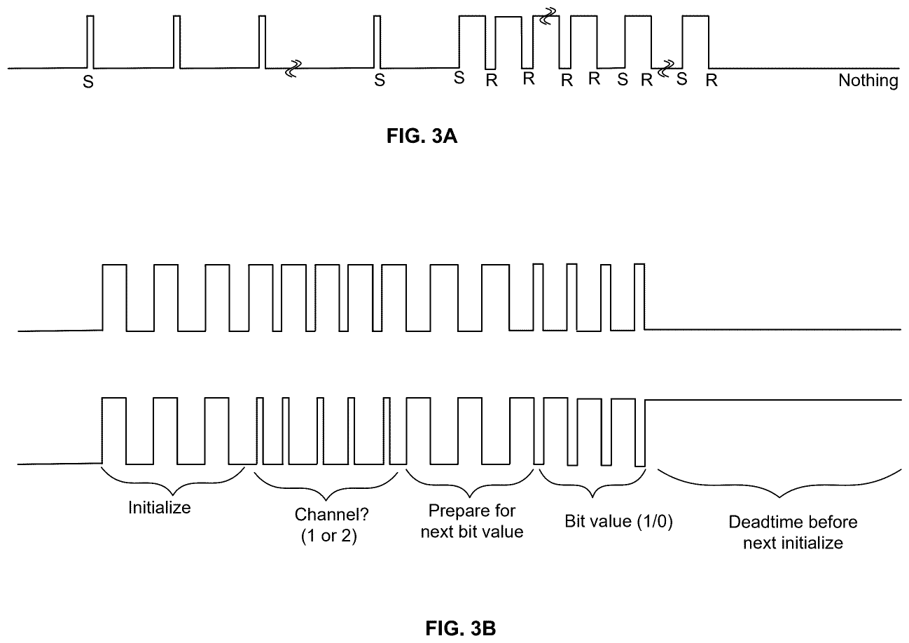

FIGS. 3A and 3B illustrate a full duplex communication scheme with multiplexed return channel, according to some embodiments. In the illustrated communication scheme, the feedback channel 104 can transmit either consecutive Sets, consecutive Resets, alternated S/R, or nothing. It should be understood by those skilled in the art and having the benefit of this disclosure that other patterns can be used and are within the scope of this disclosure. For example, the detector, when receiving a first edge, may blank the second edge if it comes within approximately 4 ns. The above 4 patterns can be corrupted by few S/R signals from the forward channel low-frequency modulation. However, redundancy filtering on previous pattern can be used. With these 4 patterns, the feedback channel 104 can, for example, transmit a “1” or “0” to 2 different registers, while using a single transmission channel.

In some embodiments, combination of the circuits and methods disclosed herein can be utilized to provide full duplex digital isolation. Although circuits and methods are described and illustrated herein with respect to several particular configuration of full duplex digital isolation, embodiments of the disclosure are suitable for other configurations of signal isolation in power converters. For example, solid state lighting and/or traction inverters systems can employ embodiments of the disclosure of full duplex signal isolation.

In the foregoing specification, embodiments of the disclosure have been described with reference to numerous specific details that can vary from implementation to implementation.

The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A circuit comprising:
a first transmitter circuit including a first input terminal arranged to receive a first input data and a first node arranged to transmit a first intermediate data corresponding to the first input data;
a first receiver circuit including a second node arranged to receive the first intermediate data and a first output terminal arranged to produce a first output data corresponding to the first input data;
a second transmitter circuit including a second input terminal arranged to receive a second input data and the second node, the second node further arranged to transmit a second intermediate data corresponding to the second input data; and
a second receiver circuit including the first node and a second output terminal, the first node further arranged to receive the second intermediate data, and the second output terminal arranged to produce a second output data corresponding to the second input data.

2. The circuit of claim 1, wherein the first node comprises a first pair of differential isolation capacitors.

3. The circuit of claim 2, wherein the second node comprises a second pair of differential isolation capacitors.

4. The circuit of claim 3, wherein each of the first pair of differential isolation capacitors comprises a first top plate and a first bottom plate, each of the first top plates coupled to the second node and each of the first bottom plates coupled to the first transmitter circuit.

5. The circuit of claim 4, wherein each of the first pair of differential isolation capacitors further comprises a second top plate attached to the first top plate and a second bottom plate separate from the first bottom plate.

6. The circuit of claim 5, wherein each of the second top plates is coupled to the second node and each of the second bottom plates is coupled to the second receiver circuit.

7. The circuit of claim 6, wherein each of the second pair of differential isolation capacitors comprises a third top plate and a third bottom plate, each of the third top plates coupled to a corresponding first top plate.

8. The circuit of claim 7, wherein each of the third bottom plates is coupled to the first receiver circuit.

9. The circuit of claim 8, wherein each of the second pair of differential isolation capacitors further comprises a fourth top plate attached to the third top plate and a fourth bottom plate separate from the third bottom plate.

10. The circuit of claim 9, wherein each of the fourth bottom plates is coupled to the second transmitter circuit.

11. The circuit of claim 1, wherein the first transmitter circuit and the second receiver circuit are arranged to operate with respect to a first ground, and the first receiver circuit and the second transmitter circuit are arranged to operate with respect to a second ground.

12. The circuit of claim 1, wherein the second input data include fault data from a high-side of a half-bridge circuit.

13. The circuit of claim 1, wherein the second input data include over-temperature or over-current condition data from a high-side of a half-bridge circuit.

14. A method of operating a circuit, the method comprising:
providing a first transmitter circuit including a first input terminal and a first node;
providing a first receiver circuit including a second node and a first output terminal;
providing a second transmitter circuit including a second input terminal and the second node;
providing a second receiver circuit including the first node and a second output terminal;
receiving a first input data, by the first transmitter circuit;
transmitting a first intermediate data, by the first transmitter circuit, corresponding to the first input data;
receiving the first intermediate data, by the second receiver circuit; and
producing a first output data, by the first receiver circuit, corresponding to the first input data.

15. The method of claim 14, further comprising:
receiving a second input data, by the second transmitter circuit;
transmitting a second intermediate data, by the second transmitter circuit, corresponding to the second input data;
receiving the second intermediate data, by the second receiver circuit; and
producing a second output data, by the second receiver circuit, corresponding to the second input data.

16. The method of claim 14, wherein the first transmitter circuit and the second receiver circuit are arranged to operate with respect to a first ground, and the first receiver circuit and the second transmitter circuit are arranged to operate with respect to a second ground.

17. A circuit comprising:
a first transmitter circuit having a first input terminal arranged to receive first input data and a first node arranged to transmit a first intermediate data corresponding to the first input data;
a first receiver circuit having a second node arranged to receive the first intermediate data and a first output terminal arranged to produce a first output data corresponding to the first input data; and
a second transmitter circuit having a second input terminal arranged to receive a second input data and the second node, the second node further arranged to transmit a second intermediate data corresponding to the second input data.

18. The circuit of claim 17, further comprising a second receiver circuit including the first node and a second output terminal, the first node further arranged to receive the second intermediate data, and the second output terminal arranged to produce a second output data corresponding to the second input data.

19. The circuit of claim 18, wherein the first transmitter circuit and the second receiver circuit are arranged to operate with respect to a first ground, and the first receiver circuit and the second transmitter circuit are arranged to operate with respect to a second ground.

20. The circuit of claim 17, wherein the second input data include over-temperature or over-current condition data from a high-side of a half-bridge circuit.
